(19) United States
(12) Patent Application Publication
(10) Pub. No.: US 2025/0060532 A1
(43) Pub. Date: Feb. 20, 2025

(54) FERROELECTRIC DEVICE OR STRUCTURE AND A METHOD FOR PRODUCING FERROELECTRIC DEVICES OR STRUCTURES

(71) Applicant: ECOLE POLYTECHNIQUE FEDERALE DE LAUSANNE (EPFL), Lausanne (CH)

(72) Inventors: Tobias KIPPENBERG, St-Sulpice (CH); Zelin TAN, Chavannes-Renens (CH); Rui WANG, Morges (CH)

(21) Appl. No.: 18/721,566

(22) PCT Filed: Dec. 20, 2021
(86) PCT No.: PCT/IB2021/062014

§ 371 Date: Jun. 18, 2024

(51) Int. Cl. G02B 6/136; G02B 6/12; G02F 1/00; G03F 7/00

(52) U.S. Cl. CPC G02B 6/136; G02F 1/0027; G03F 7/0005; G02B 2006/1204; G02B 2006/12173; G02F 2202/20

(57) ABSTRACT

The present invention concerns a method for producing at least one ferroelectric device or structure comprising the steps of providing at least one ferroelectric material or layer, or providing at least one ferroelectric material or layer to be patterned or structured; depositing at least one adhesion layer on a first side of the at least one ferroelectric material or layer; and depositing at least one diamond-like carbon layer or material on the at least one adhesion layer.

### FIELD OF THE INVENTION

The present invention relates to ferroelectric devices or structures as well as a method for producing or fabricating at least one or a plurality of ferroelectric devices or structures. The ferroelectric devices or structures may, for example, comprises or consists of photonic devices, or integrated photonic devices such as but not limited to integrated photonic waveguides, resonators and electro-optic devices.

### BACKGROUND

Ferroelectric material such as Lithium niobate is of particular interest, for example, for linear and non-linear optical devices such as electro-optic devices, acousto-optic devices, optical waveguides, optical modulators, optical switches, frequency converters and piezoelectric sensors.

However, the fabrication of ferroelectric devices or structures, such as Lithium niobate structures or devices, having high performance characteristics is challenging. Lithium niobate for example is a hard and chemically inert material and difficult to etch. Unlike, for example Silicon, it cannot be satisfactorily chemically etched to fabricate nanometer or high aspect ratio optical waveguides.

The devices produced have, for example, significant optical loss and/or insufficient structural aspect ratios that prevents high performance optical devices being obtained. Furthermore, a lengthy manufacturing time is required and often a stitching approach is used during fabrication which leads to production misalignments at the stitching between regions. Wafer scale manufacturing is not currently possible.

U.S. Pat. No. 11,086,048 discloses a method for fabricating Lithium niobate devices.

An alternative fabrication method concerns a hybrid approach involving bonding Lithium niobate material onto a Silicon substrate by flip-bonding and employing an adhesive bonding process (He et al, Nature Photonics, Vol. 13, May 2019 359-364, https://doi.org/10.1038/s41566-019-0378-6).

The present invention addresses the above-mentioned inconveniences. The present invention also provides an alternative to known fabrication methods.

### SUMMARY OF THE INVENTION

The present invention addresses the above-mentioned limitations by providing a method for producing at least one or a plurality of ferroelectric devices or structures. The method includes the steps of providing at least one ferroelectric material or layer, or providing at least one ferroelectric material or layer to be patterned or structured; depositing at least one adhesion layer on a first side of the at least one ferroelectric material or layer; and depositing at least one diamond-like carbon layer or material on the at least one adhesion layer.

The present invention addresses the above-mentioned limitations by providing a ferroelectric device or structure comprising at least one ferroelectric material or layer, at least one adhesion layer on a first side of the at least one ferroelectric material or layer; and at least one diamond-like carbon layer or material on the at least one adhesion layer.

The present invention addresses the above-mentioned limitations by providing a ferroelectric device or structure comprising at least one ferroelectric material or layer, at least one adhesion layer on a first side of the at least one ferroelectric material or layer; at least one diamond-like carbon layer or material on the at least one adhesion layer; at least one further adhesion layer on a second side of the at least one ferroelectric material or layer, and at least one diamond-like carbon layer or material on the at least one further adhesion layer on the second side of the at least one ferroelectric material or layer.

Other advantageous features can be found in the dependent claims.

The structure, device and method of the present disclosure permits, for example, wafer-scale fabrication of superior integrated photonic devices on ferroelectric thin-film platforms, such as lithium niobate.

The utilization and accommodation of, for example, diamond-like carbon thin-films as a mask material in the etching process is advantageous and permits the design and provision of structures and devices having high performance characteristics. Owing to its very low sputtering yield, this material is very resistant to, for example, physical etching by ion bombardment. This allows the ferroelectric material below to be etched smoothly while retaining good verticality and pronounced fidelity to the intended design or pattern. This innovative process can produce integrated photonic devices that yield superior performances than what is achieved with known etch-masks.

Known etch-masks undergo mask erosion limiting the height or profile of optical structures or devices such as waveguides. The method and device of the present disclosure permit the production of high quality and low loss ferroelectric (for example, Lithium Niobate) integrated photonics with high aspect ratios.

Another key advantage is that the hard mask fabrication process of the present disclosure is compatible with DUV wafer scale processing and enables to produce, for example, LNOI based integrated photonic waveguides.

The method and device of the present disclosure permits DUV compatible wafer scale manufacturing of high quality and low loss ferroelectric (for example, Lithium niobate) integrated photonics with high aspect ratios.

The above and other objects, features, and advantages of the present invention and the manner of realizing them will become more apparent, and the invention itself will best be understood from a study of the following description with reference to the attached drawings showing some preferred embodiments of the invention.

### A BRIEF DESCRIPTION OF THE SEVERAL VIEWS OF THE DRAWINGS

FIGS. 1A to 1K show an exemplary method for producing at least one or a plurality of ferroelectric devices or structures according to the present disclosure. The method steps are not necessarily carried out in the order shown and not all steps are necessarily carried out.

FIGS. 2A to 2N show another exemplary method for producing at least one or a plurality of ferroelectric devices or structures according to the present disclosure. The method steps are not necessarily carried out in the order shown and not all steps are necessarily carried out.

FIGS. 3A to 3D show different ferroelectric devices or structures, these ferroelectric devices or structures are produced as intermediate products by the method according to the present disclosure.

FIGS. 4 to 10 are SEM images of ferroelectric devices or structures produced by the method of the present disclosure.

FIG. 4 is a cross sectional SEM image of a Lithium niobate waveguide etched with a diamond-like carbon DLC etch mask, after redeposition cleaning and mask removal. The starting Lithium niobate film thickness is 700 nm, 620 nm were etched and 80 nm remain. The sidewall angle is 77°.

FIG. 5 is a tilted SEM image of a sidewall of a Lithium niobate waveguide etched with a diamond-like carbon DLC etch mask, after redeposition cleaning and mask removal.

FIGS. 6 to 10 are tilted SEM images showing examples of integrated Lithium niobate photonic devices after Lithium niobate etching, redeposition cleaning, and mask removal. FIGS. 6 to 10 respectively show a 100 GHz FSR ring resonator, coupled ring resonators, a very thin tapered waveguide, 2-2 splitters, and a Y-splitter.

The materials indicated in the Figures are provided by way of example and the method, devices and structures of the present disclosure are not limited to the specific details indicated in the Figures.

Herein, identical reference numerals are used, where possible, to designate identical elements that are common to the Figures.

### DETAILED DESCRIPTION OF SEVERAL EMBODIMENTS

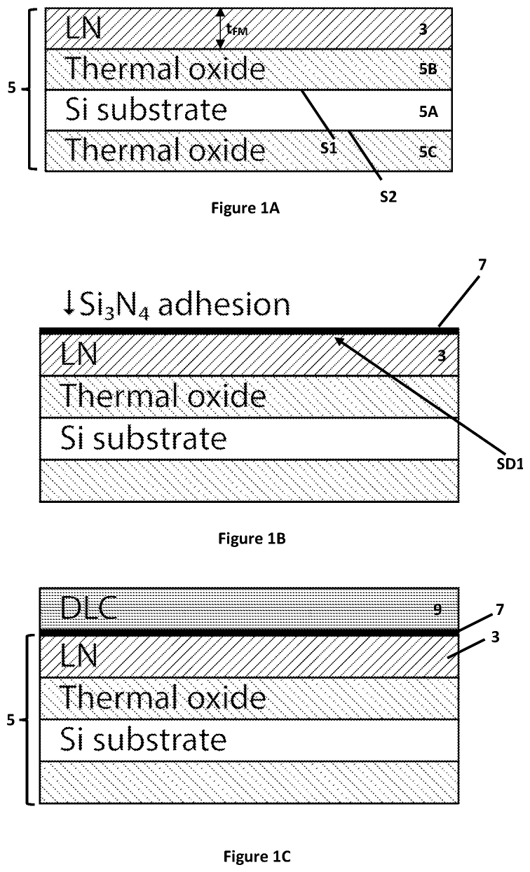

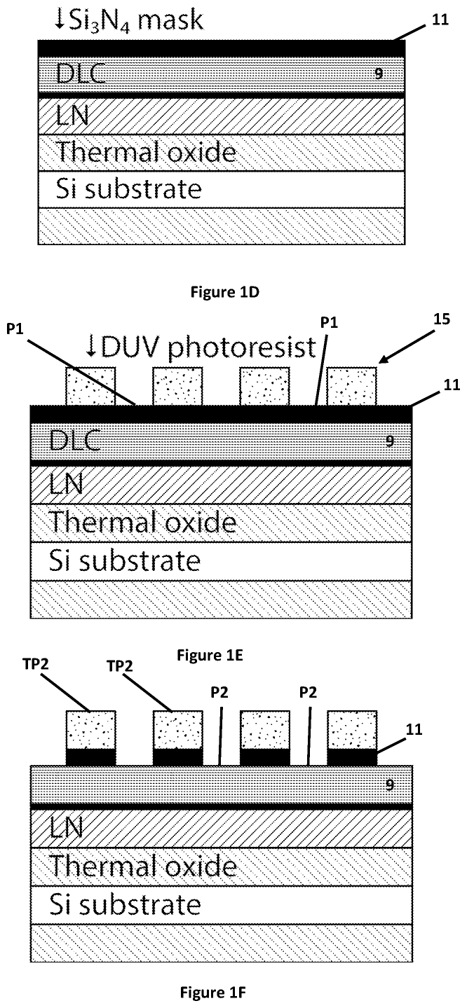

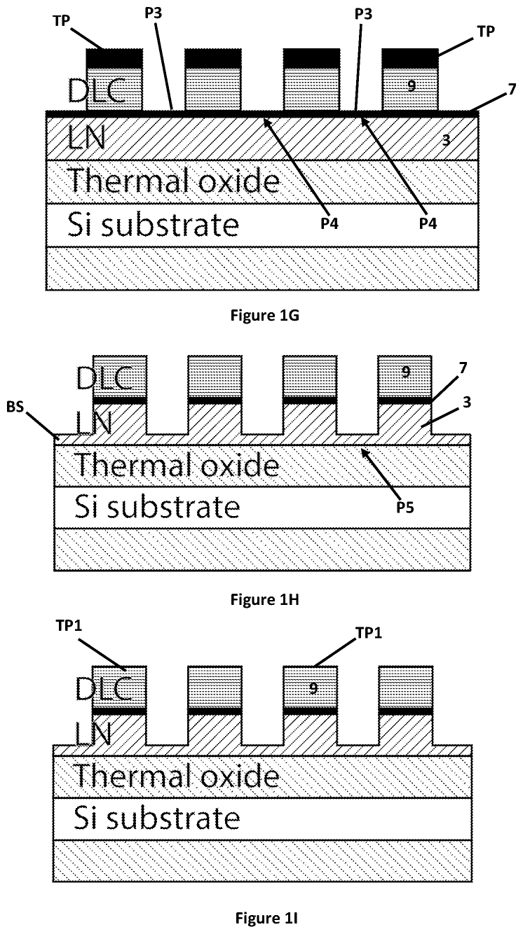

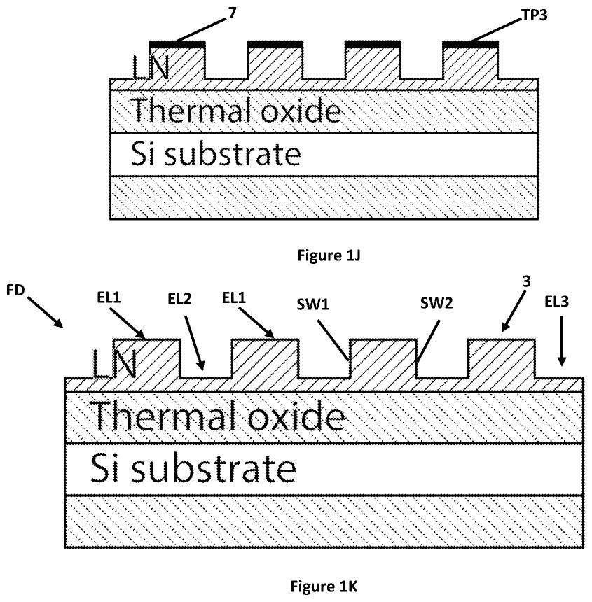

FIGS. 1A to 1K show exemplary steps of an exemplary embodiment of a fabrication method according to the present disclosure. The method steps are not necessarily carried out in the order shown and not all steps are necessarily carried out.

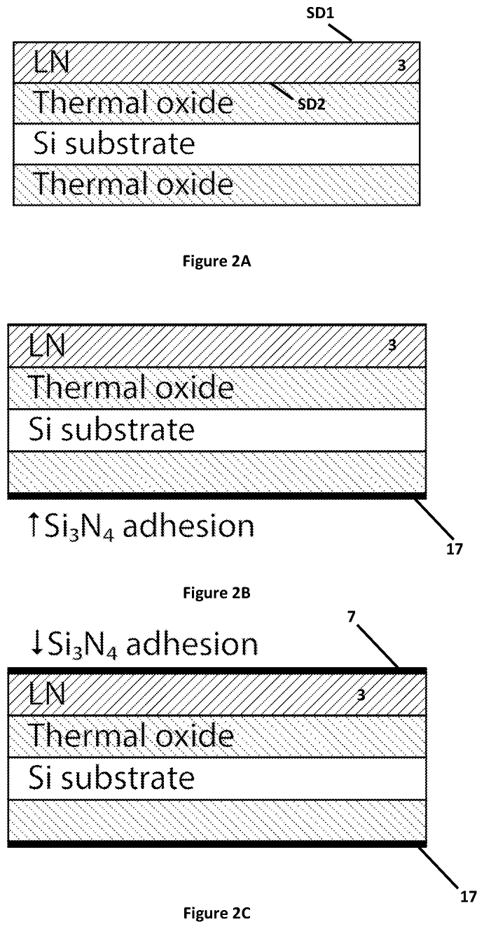

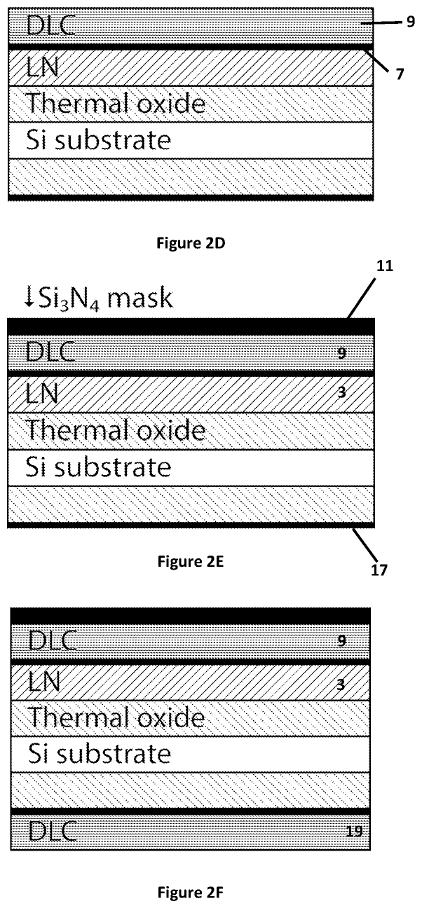

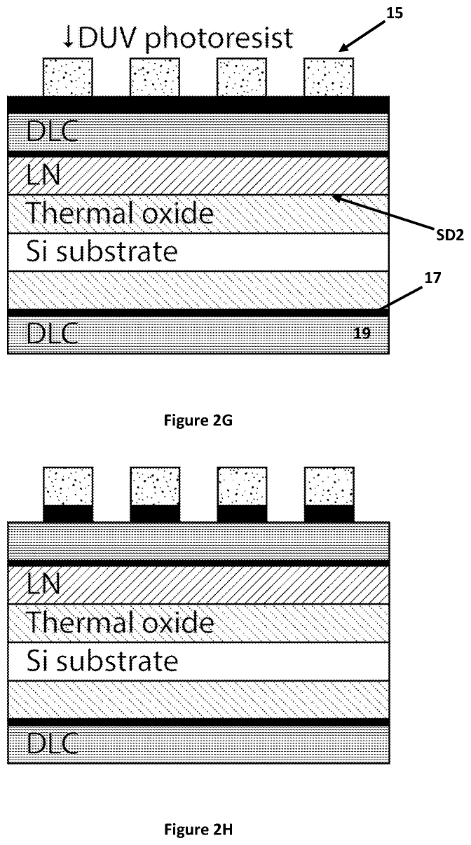

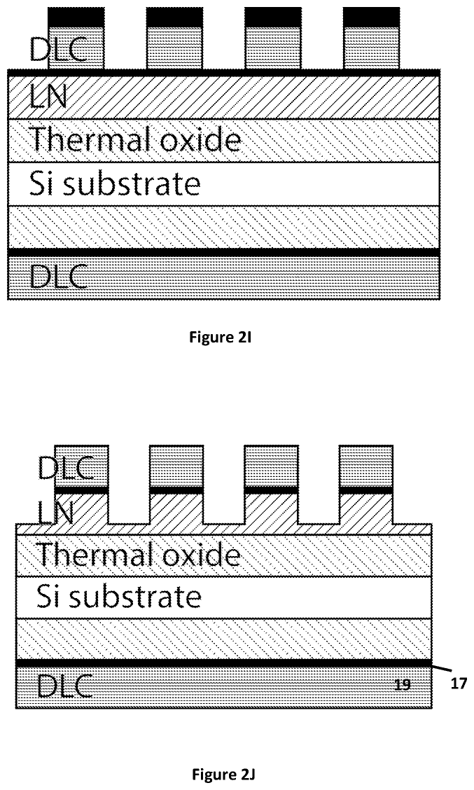

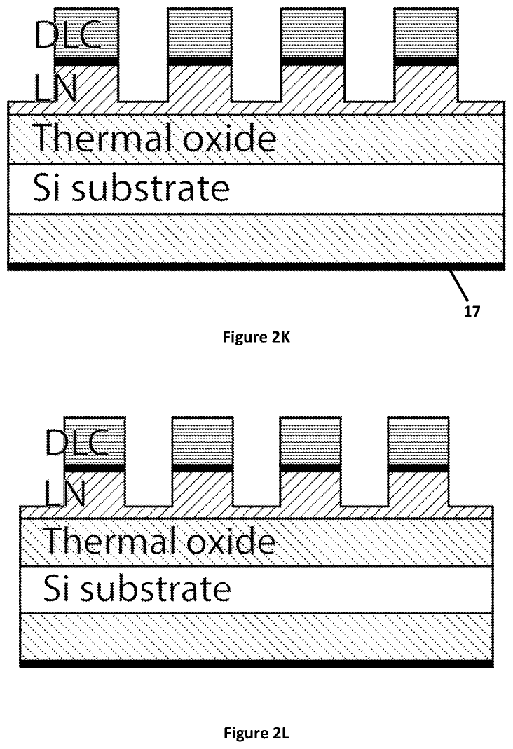

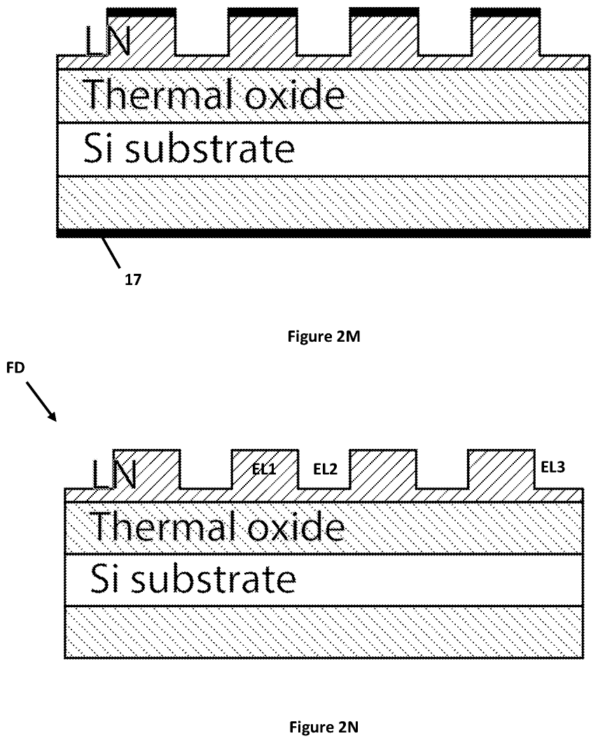

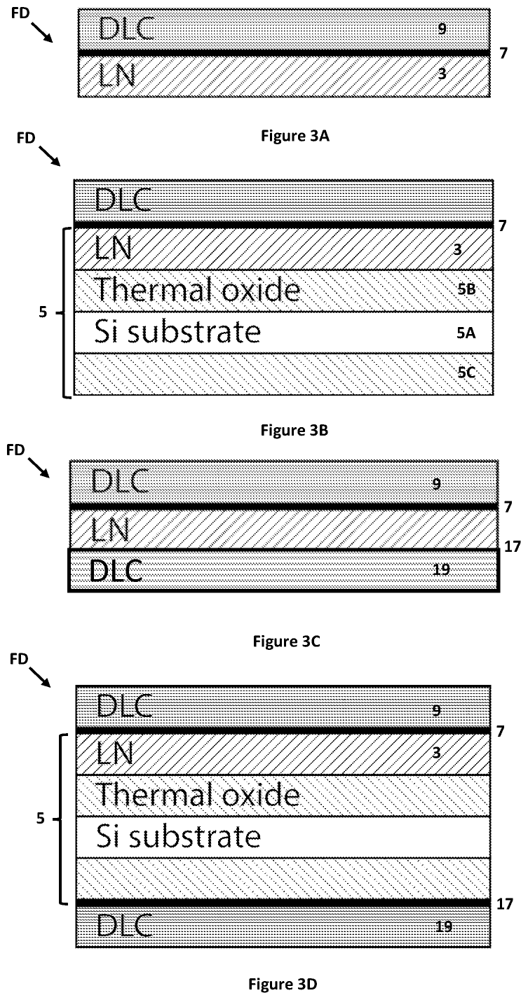

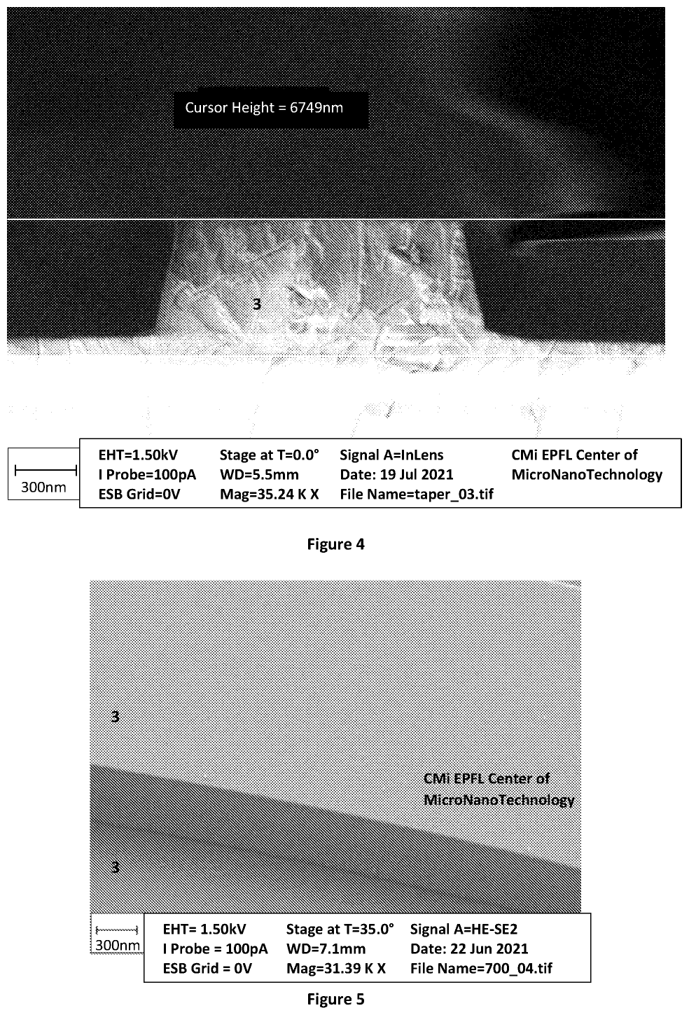

The method produces a ferroelectric device or ferroelectric structure FD. The ferroelectric device or structure FD may include a ferroelectric layer or material 3 as for example shown in FIGS. 3A to 3D, or may include or consist of a ferroelectric layer or material 3 that is patterned or structured as for example shown in FIGS. 1K and 2N.

The ferroelectric device or structure FD may include other materials or layers provided above and/or below the ferroelectric layer or material 3.

The patterned or structured ferroelectric layer or material 3 includes or defines one or more elements EL that may define features or components of devices, such as features or components of optical or opto-electronic devices.

These elements EL may include, for example, protrusions EL1, depressions EL2 or openings EL3 extending partially or fully through ferroelectric layer or material 3. These elements may extend across the ferroelectric layer or material 3 to define an elongated device or structure. For example, a device or structure may comprise or consist of a protrusion EL1 defined by a first and second depression EL2 (or a depression EL2 and an opening EL3) defining a first side wall SW1 and a second side wall SW2 of the device or structure.

The structured or patterned ferroelectric layer or material 3 may be part of a device that includes other materials or elements located above and/or below the ferroelectric layer or material 3. For example, in the case where the ferroelectric layer or material 3 is included in or as part of a ferroelectric on insulator wafer such as a Lithium niobate on insulator (LNOI) wafer, Silicon electronics may be used for electronic or electrical control of the structured or patterned ferroelectric layer or material 3 which may also for example include electrodes contacted thereto.

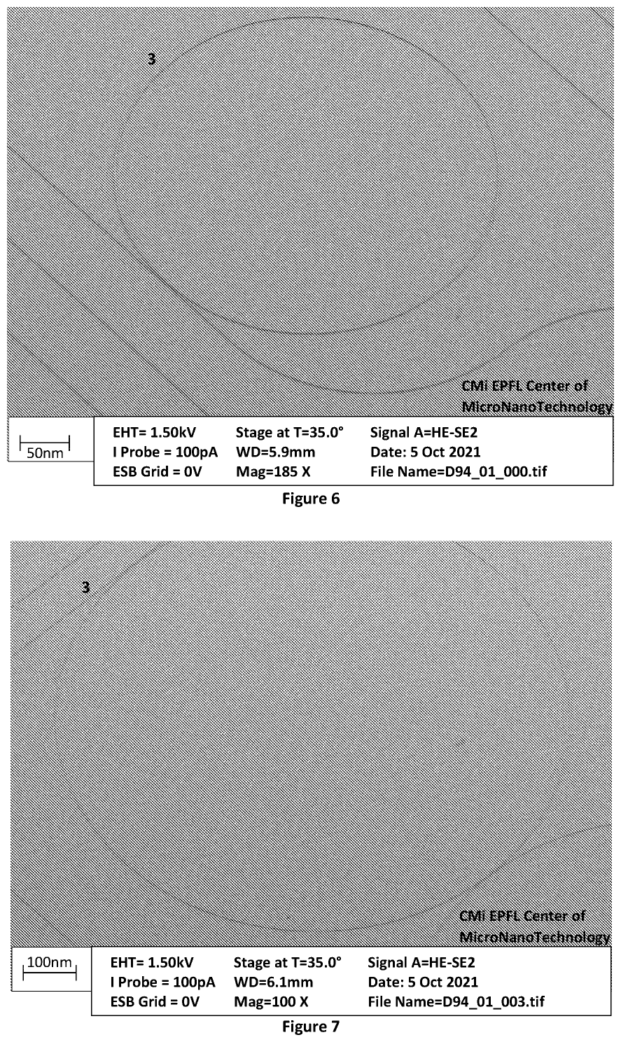

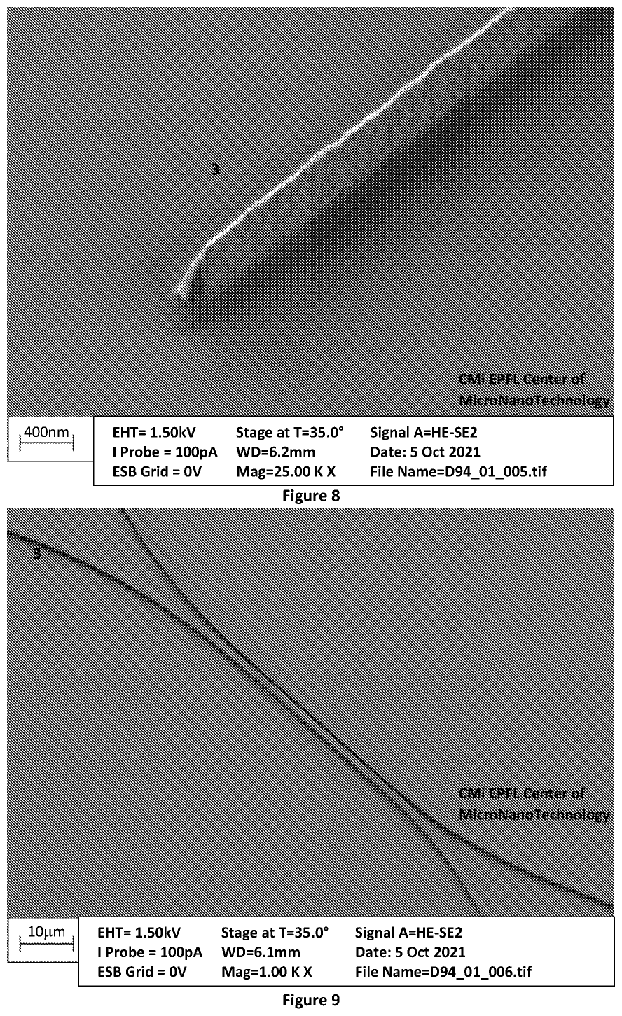

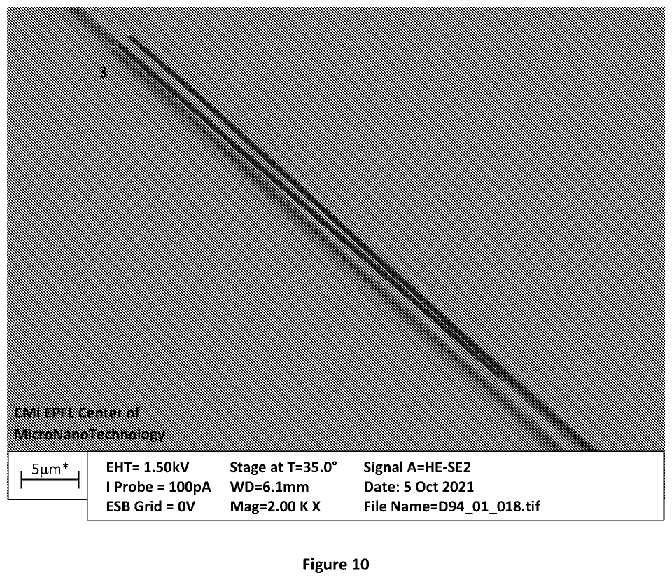

The structured or patterned ferroelectric layer or material 3 may, for example, include, define or be part of a plurality of interconnected devices such as interconnected or integrated photonic devices. FIGS. 6 to 10 show exemplary devices but other devices and device configurations are also possible.

As mentioned, the ferroelectric device or structure FD may include a ferroelectric layer or material 3 that is for example non-patterned or non-structured, as for example shown in FIGS. 3A to 3D. These ferroelectric devices or structures FD are, for example, intermediate products that are (DUV) photolithography-ready. This facilitates large scale and high frequency production of ferroelectric devices, for example, to produce Lithium niobate integrated photonics.

The method of the present disclosure is a wafer bonding-less method or an adhesive wafer bonding-less method.

The method for producing the ferroelectric device or structure FD includes providing at least one ferroelectric material or layer 3 or providing at least one ferroelectric material or layer 3 to be patterned or structured.

The ferroelectric material or layer 3 that is provided may, for example, be a carrier or support that consists solely of the ferroelectric material.

Alternatively, the ferroelectric material or layer 3 may be provided, for example, as part of be a carrier, wafer or support that includes the ferroelectric material or layer 3 and further includes other layers or materials, for example, included as underlayers below the ferroelectric material or layer 3. The ferroelectric material or layer 3 may, for example, be provided on a substrate consisting of a different material to that of the ferroelectric material or layer 3. The ferroelectric material or layer 3 may be provided directly or indirectly on the substrate layer.

For example, the ferroelectric material or layer 3 may be included in or as part of a ferroelectric on insulator wafer or carrier 5 (see, for example FIG. 1A). The ferroelectric on insulator wafer or carrier 5 may comprise or consist of a substrate 5A, at least one oxide layer 5B provided on the substrate 5A and at least one ferroelectric material or layer 3 provided on the oxide layer 5B. A further oxide layer 5C may also be provided on the opposite substrate side S2 opposite to the side S1 to which the oxide layer 5B is located between the ferroelectric material 3 and the substrate 5A.

The ferroelectric material or layer 3 may, for example, be part of or included in a Lithium niobate on insulator (LNOI) wafer or carrier 5 as shown in the exemplary and non-limiting embodiments of the Figures (see, for example, FIG. 1A and 2A). The Lithium niobate on insulator wafer 5 comprises or consists of a substrate 5A, at least one oxide layer 5B provided (for example, directly) on the substrate 5A and at least one Lithium Niobate (LiNbO₃) layer or material 3 provided (for example, directly) on the oxide layer 5B. The Lithium Niobate on insulator wafer 5 may also further include at least one further oxide layer 5C provided on the substrate 5A on the opposite side S2 of the substrate 5A to that of the at least one oxide layer 5B.

The substrate 5A may, for example, comprise or consist of Silicon. The oxide layers 5B, 5C may comprise or consist of thermal oxide layers. The oxide layers 5B, 5C may comprise or consist of silicon oxide (SiO₂).

The ferroelectric material or layer 3 may, for example, be doped or undoped and/or a single crystal material.

The ferroelectric material or layer 3 may, for example, comprises or consists solely of Lithium Niobate (LiNbO₃), or single crystal Lithium Niobate (LiNbO₃). The ferroelectric material or layer 3 may comprise or consist solely of doped or undoped Lithium Niobate (LiNbO₃) or doped or undoped single crystal Lithium Niobate (LiNbO₃).

The ferroelectric material or layer 3 may, for example, comprises or consists solely of Lithium Tantalate (LiTaO₃), or Barium titanate BTO or Gallium phosphide GaP.

The provided ferroelectric material or layer 3 may, for example, have a thickness t_{FM} (before etching) between 100 nm and 10 μm, or between 250 nm and 1 μm, for example 500 nm or 700 nm.

For example, the Lithium niobate on insulator (LNOI) wafer or carrier 5 may include a Lithium niobate layer having a thickness t_{FM} of 500 nm or 700 nm, a substrate 5A of thickness between 500 μm and 1000 μm (for example, 500 μm or 700 μm), a first or upper oxide layer 5B of thickness between 3 μm and 7 μm (for example, 4.7 μm), and a second or lower oxide layer 5C of thickness between 3 μm and 7 μm (for example, 4.7 μm).

As shown for example in FIG. 1B, at least one adhesion layer 7 may be deposited or provided on a first side SD1 of the ferroelectric material or layer 3. At least one diamond-like carbon layer or material (DLC) 9 may be provided or deposited on the adhesion layer 7 (FIG. 1C).

The adhesion layer 7 is configured to assure adhesion of the diamond-like carbon layer or material (DLC) 9 to the ferroelectric material or layer 3 in particular during processing of the device or structure.

The adhesion layer 7 is configured to prevent delamination of the diamond-like carbon layer or material 9 from the ferroelectric material or layer 3.

The adhesion layer 7 is, for example, deposited directly on the first side SD1 of the ferroelectric material or layer 3, or directly in contact with the first side SD1 of the ferroelectric material or layer 3.

The adhesion layer 7 may comprise or consist of, for example, Silicon Nitride (Si₃N₄), Silicon Oxide (SiO₂) or Sapphire (Al₂O₃).

The adhesion layer 7 can, for example, be deposited by chemical vapor deposition, for example, plasma-enhanced chemical vapor deposition (PECVD). An adhesion layer 7 thickness of between 20 and 60 nm may, for example, be deposited. For example, 30 nm of Silicon Nitride (Si₃N₄) may be deposited by PECVD as the adhesion layer 7. Deposition may, for example, be carried out using a standard recipe for Si₃N₄ with, for example, an Oxford Instruments PlasmaPro 100 PECVD tool. The following deposition parameters may, for example, be used: Chamber pressure=800 mTorr, RF power=40 W, SiH4/N4 (2%) gas flow: 1000 sccm, NH3 gas flow=15 sccm, bottom electrode temperature=300 ° C., deposition time=1 min.

As mentioned, in a preferred embodiment, a diamond-like carbon layer or material (DLC) 9 is provided or deposited on the adhesion layer 7 (FIG. 1C). The diamond-like carbon layer or material (DLC) 9 defines a hard mask layer and acts as a hard mask.

The diamond-like carbon layer or material 9 is, for example, deposited directly on the adhesion layer 7 deposited on the first side SD1 of the ferroelectric material or layer 3.

The diamond-like carbon layer or material 9 can be, for example, deposited on the adhesion layer 7 by a chemical vapor deposition (CVD) process. The thickness of the diamond-like carbon layer or material 9 may, for example, be between 200 nm and 1000 nm, for example 500 nm. Deposition can be carried out, for example, in the reactive-ion etching chamber of an Oxford Instruments PlasmaPro 80. The following deposition parameters may, for example, be used: Chamber pressure=30 mTorr, 200 W DC bias, 50 sccm CH4 gas flow. Prior to the deposition, a surface cleaning step may be carried out, for example, for 2 minutes at a pressure of 40 mTorr, with 150 W DC bias power, and with a gas flow of 50 sccm of Argon.

The diamond-like carbon layer or material 9 may alternatively, for example, be deposited on the adhesion layer 7 by a physical vapor deposition process.

The Inventors have found that the diamond-like carbon layer or material is resistant to etching and in particular to physical etching by ion bombardment and has a very low sputtering yield. The diamond-like carbon layer or material dictates the selectivity of the etch rate compared to the etch rate of ferroelectric material and allows the ferroelectric material below to be etched smoothly while retaining excellent verticality and excellent fidelity to the intended design or pattern to be transferred to the ferroelectric material. The production of integrated photonic devices yielding superior performances than what is achieved with prior art etch-masks is thus possible.

Diamond-like carbon layer or material (DLC) 9 may, for example, comprise or consist of a non-crystalline material or an amorphous carbon layer/film or carbon material.

Diamond-like carbon layer or material (DLC) 9 may, for example, comprises or consists of an amorphous carbon film and sp³-hybridized carbon atoms and Hydrogen.

The layer or material may have, for example, no long-range crystalline order. Diamond-like carbon layer or material (DLC) 9 may, for example, comprise or consist of microcrystalline or nanocrystalline diamond and graphite.

It shows properties typical of diamond such as significant hardness. Diamond-like carbon layer or material (DLC) 9 is a different material to natural diamond or synthetic diamond and does not comprise or consist of natural diamond or synthetic diamond.

Details of Diamond-like carbon layer or material (DLC) 9 can, for example, be found in Carbon Alloys, Novel Concepts to Develop Carbon Science and Technology 2003, Pages 545-558, Chapter 34—Super Hard materials, by Osamu Takai, https://doi.org/10.1016/B978-008044163-4/50034-6, and Properties and Classification of Diamond- Like Carbon Films, by Naoto Ohtake et al, Materials 2021, 14 (2), 315, https://doi.org/10.3390/ma14020315, the entire contents of which is incorporated herein.

The diamond-like carbon layer or material 9 may, for example, be an internal or intrinsically stress-compensated layer or compressive stress-compensated layer.

While a preferred embodiment uses a diamond-like carbon layer or material (DLC) 9 as a hard mask, it should be noted that an alternative hard mask layer may, for example, comprise or consist of at least one Silicon Carbide (SiC) layer or material.

As shown, for example, in FIG. 1D, a capping layer 11 may be provided or deposited on the diamond-like carbon layer or material 9. It is deposited (indirectly) on the first side SD1 of the ferroelectric material or layer 3. The capping layer 11 may be provided or deposited directly on the diamond-like carbon layer or material 9 and be directly in contact with the diamond-like carbon layer or material 9.

The provision or deposition of capping layer 11 further assures reliable and reproducible deposition of stable diamond-like carbon layer or material 9 that does not delaminate. The Inventors have found that the diamond-like carbon layer or material 9 does not delaminate even after storage in air for weeks or even months.

The capping layer 11 may be or act as a mask layer. The layer 11 may be a capping layer and/or a mask layer. The layer 11 may be a mask layer or hard mask layer for or during the etching of the diamond-like carbon layer or material 9 to transfer a pattern or structure into the diamond-like carbon layer or material 9. The layer 11 may be partially removed during etching of the ferroelectric material or layer 3.

A thickness t_{cl} of the capping layer 11 is, for example, less than a thickness t_{DLC} of the at least one diamond-like carbon layer or material. The thickness t_{DLC} of the diamond-like carbon layer or material 9 is, for example, between 5 times and 10 times greater than the thickness tₘₗ of the capping layer 11.

The capping or mask layer 11 may comprise or consist of the same material as the adhesion layer 7.

The capping or mask layer 11 may, for example, comprise or consist of Silicon nitride (Si₃N₄) or Sapphire or amorphous silicon.

The thickness t_{cl} of the capping or mask layer 11 may be, for example, between 20 and 100 nm, for example 60 nm.

The capping or mask layer 11 can, for example, be deposited by chemical vapor deposition, for example, plasma-enhanced chemical vapor deposition (PECVD). A layer of between 20 and 100 nm may, for example, be deposited. For example, 60 nm of Silicon Nitride (Si₃N₄) may be deposited by PECVD. Deposition may, for example, be carried out using a standard recipe for Si₃N₄ with for example an Oxford Instruments PlasmaPro 100 PECVD tool. The following deposition parameters may, for example, be used: Chamber pressure=800 mTorr, RF power=40 W, SiH4/N4 (2%) gas flow: 1000 sccm, NH3 gas flow=15 sccm, bottom electrode temperature=300 ° C., deposition time=1 min.

As shown, for example, in FIG. 1E, the method of the present disclosure may further include carrying out a photolithography process to provide at least one patterned or structured photoresist layer 15 on (or directly on) the capping or mask layer 11. The patterned or structured photoresist layer 15 exposes one or a plurality of portions or surfaces P1 of the capping or mask layer 11, as seen for example in FIG. 1E.

In the (partial) absence of the capping or mask layer 11, the patterned or structured photoresist layer 15 exposes one or a plurality of portions or surfaces P2 of the at least one diamond-like carbon layer or material 9.

The photolithography process comprises or consists of an ultraviolet or deep ultraviolet (DUV) photolithography process. The photolithography process may be carried out, for example, using stepper photolithography or step-and-repeat camera photolithography.

The process may include the following steps. A photoresist layer 15 may be coated or deposited (for example, directly) onto the capping or mask layer 11.

Photolithography or UV lithography is used to transfer a (geometric) pattern or structure from a photomask or optical mask to the photosensitive photoresist. Deep ultraviolet (DUV) photolithography using, for example, light of wavelength <400 nm, for example, in the range 193 nm-254 nm illuminates the photomask to define an exposure pattern on and in the photoresist such that the resulting polymer pattern can be transferred into the underlying layers or materials by etching.

The exposure UV or DUV light is passed through, for example, a chrome-on-quartz photomask, whose opaque areas act as a stencil of the desired pattern. The photoresist layer 15 may be baked before and/or after light exposure. The exposed photoresist areas then undergo a chemical development to remove unwanted photoresist areas (photoresist remains in areas where the photomask blocked light exposure) and producing areas P1 that are open or exposing an underlying material or layer (for example, layer or material 11) that can be subsequently processed.

An ASML PAS 5500/350C Deep-UV stepper photolithography tool was used, for example, to expose and produce the devices shown in FIGS. 6 to 10. The photoresist coating and development was performed, for example, using an in-line TEL Clean Track ACT-8 tool. The photoresist may, for example, be 400 nm thick M108Y (6cP) DUV photoresist from JSR Micro NV, on top of 60 nm of DUV42P as bottom layer anti-reflective coating (BARC). Coating/exposure/development may be performed, for example, using the standard recipes provided by the vendor.

The above-described approach is a positive photoresist exposure approach. Alternatively, a negative photoresist exposure approach may also be used using negative photoresist.

Optionally, and prior to deposition of the photoresist layer 15, a bottom anti-reflection coating may be deposited, for example, of thickness 60 nm. This allows to reduce light reflections emanating from layers or materials underlying the photoresist layer 15.

The result of the photolithography process is the patterned or structured photoresist layer 15. The pattern or structure of the photoresist layer 15 will be transferred into the underlying layers or materials, including into the diamond-like carbon layer or material 9 and into the ferroelectric layer or material 3 to define the elements EL (FIG. 1K) that define features or components of devices.

The photolithography process fully removes sections through the thickness of the photoresist material to expose one or a plurality of portions P1 of the capping or mask layer 11, as seen for example in FIG. 1E, or one or a plurality of portions P2 of the diamond-like carbon layer or material 9.

As shown in FIG. 1F, etching may be carried out to etch the capping or mask layer 11. Etching is carried out to etch the exposed portion or portions P1 of the capping or mask layer 11 to remove the exposed capping or mask layer/material 11 (and material underneath) and to expose one or a plurality of portions P2 of the diamond-like carbon layer or material 9 located under the capping or mask layer 11. The pattern of the photoresist layer 15 is transferred to the capping or mask layer or material 11.

The etching of mask material 11 is carried out by plasma-etching, for example, using an SPTS Advanced Plasma System with an ICP-based high density plasma source. The following etching parameters may, for example be used: Chamber pressure=15 mTorr, 50 sccm CHF3 and 10 sccm SF6 gas flow, 13.56 MHz coil power=950 W, 13.56 MHz platen power=50 W, platen temperature=10° C. Prior to the etching of capping or mask layer 11, a BARC opening step may, for example, be performed using the following parameters with the same tool: Chamber pressure=15 mTorr, 10 sccm O2 and 10 sccm CHF3 gas flow, 13.56 MHz coil power=950 W, 13.56 MHz platen power=50 W, platen temperature=10° C.

As shown in FIG. 1G, etching may be carried out to etch the diamond-like carbon layer or material 9. Etching is carried out to etch the exposed portion or portions P2 of the diamond-like carbon layer or material 9 to remove the exposed diamond-like carbon layer or material 9 (and material underneath) and to expose one or a plurality of portions P3 of the adhesion layer 7 located under the diamond-like carbon layer or material 3. The pattern of the photoresist layer 15 is transferred to the hardmask DLC layer 9.

The etching of the hardmask DLC layer 9 is carried out by plasma-etching with O₂, for example, using an SPTS Advanced Plasma System with an ICP-based high density plasma source. The following etching parameters may, for example be used: Chamber pressure=50 mTorr, 100 sccm O₂ gas flow, 13.56 MHz coil power=2000 W, 13.56 MHz platen power=200 W, platen temperature=10° C.

Etching of the patterned or structured photoresist layer or material 15 may be carried out to remove or fully remove the patterned or structured photoresist layer or material 15 (remaining top portions TP2). This may be done using the same plasma etch used for etching the diamond-like carbon layer or material 9. Etching of the patterned or structured photoresist layer or material 15 and the diamond-like carbon layer or material 9 may be done simultaneously.

As shown in FIG. 1H, for example, etching may be carried out to etch the adhesion layer or material 7. Etching is carried out to etch the exposed portion or portions P3 of the adhesion layer or material 7 to remove the exposed adhesion layer or material 7 (and material underneath) and to expose one or a plurality of portions P4 (FIG. 1G) of the ferroelectric material or layer 3 located under the adhesion layer 7. The pattern of the photoresist layer 15 is transferred to the adhesion layer or material 7.

As also shown in FIG. 1H, for example, etching may be carried out to etch the ferroelectric material or layer 3. This may for example be carried out by continuous etching continued after etching fully through the exposed portions of the adhesion layer or material 7.

Etching is carried out to etch the exposed portion or portions P4 of the ferroelectric material or layer 3 to remove the exposed ferroelectric material or layer 3 and material (directly) underneath.

The pattern of the photoresist layer 15 is transferred to the ferroelectric material or layer 3 material, after having been transferred to the upper layers or material.

The ferroelectric material or layer 3 may be partially etched (as seen in FIG. 1H). This, for example, may permit to create a lower support layer. The ferroelectric material or layer 3 may be fully etched through to expose one or a plurality of portions of P5 of any underlying layer or material 5B, 5A.

The pattern of the photoresist layer 15 is transferred to the ferroelectric material or layer 3 to define the elements EL (FIG. 1K) that define features or components of devices of the ferroelectric device or structure FD.

The etching is carried out to at least partially produce one or more ferroelectric devices or structures, or photonic devices, or integrated photonic devices that may comprise or be defined, for example, by the elements EL transferred to the ferroelectric material or layer 3 material.

The etching of ferroelectric material or layer 3 and the adhesion layer or material 7 is, for example, carried out by ion beam etching. The etching is carried out by ion beam etching consisting of, for example, using a Nexus IBE350 tool from Veeco. The tool uses an Argon ion source with RF plasma generator of 1.8 MHz, with power up to 2000 W. The ions are accelerated and collimated through 3-grids optics.

The ion beam may be incident at an angle relative to the surface to be etched or the intermediate ferroelectric device or structure, for example at an angle of 10° or 30°, and generated with a power up to 2000 W, or with alternating steps at varying angles and power.

The etching may, for example, be performed in such a way as to leave a thin 50 nm to 100 nm slab or base BS of ferroelectric material or layer 3, thus not entirely etching through the ferroelectric material or layer 3.

An etch depth of 620 nm was, for example, obtained into the ferroelectric material 3 of Lithium Niobate in the case of the devices shown in FIGS. 6 to 10.

The structured or patterned ferroelectric material or layer 3 produced by the ion beam etching may then be cleaned to remove ferroelectric material redeposition that may have occurred during the ion beam etch (FIG. 11). This cleaning step may, for example, be carried out for 4 minutes using a 2:2:1 ratio (weight) solution of ammonia (NH3 28-30%), hydrogen peroxide (H2O2 3%), and DI water heated at 85°° C. (concentrated RCA1 solution).

This same ion beam etching may also be used to remove any remaining top portions TP (FIG. 1G) of the mask or capping layer or material 11 located on top of the diamond-like carbon layer or material 9 on the top portions TP1 (FIG. 11). Top portion TP of the mask or capping layer 11 is, for example, removed simultaneously during etching of the adhesion layer 7 and/or the ferroelectric material 3.

As shown, for example, in FIG. 1J, the remaining or top portions TP1 (FIG. 11) of the diamond-like carbon layer or material 9 located on top of the adhesion layer or material 7 and/or the ferroelectric material or layer 3 are removed.

The etching of the remaining or top portions TP1 (FIG. 11) of the diamond-like carbon layer or material 9 can be carried out, for example, by plasma-etching with O2. This can be done, for example, using an SPTS Advanced Plasma System with an ICP-based high density plasma source. The following etching parameters may, for example be used: Chamber pressure=50 mTorr, 100 sccm O₂ gas flow, 13.56 MHz coil power=2000 W, 13.56 MHz platen power=200 W, platen temperature=10° C.

As shown, for example, in FIG. 1K, the remaining or top portions TP3 (FIG. 1J) of the adhesion layer or material 7 located on top of the ferroelectric material or layer 3 are removed.

The etching is carried out by a wet etch, for example, using a buffered HF (hydrofluoric acid) solution.

One or more electrodes may be provided or deposited on the ferroelectric material or layer 3 to electrically address devices or components formed by the above-described etching process. At least one cladding material may also be provided or deposited on the ferroelectric material or layer 3.

The ferroelectric devices or structures may comprise or consist of photonic devices, or integrated photonic devices.

The ferroelectric material or layer 3 or the device or structure, for example of FIG. 1K, may be separated or diced into a plurality of ferroelectric chips or subdivisions.

FIGS. 2A to 2N shows another exemplary method for producing at least one or a plurality of ferroelectric devices or structures according to the present disclosure. The method steps are not necessarily carried out in the order shown. Not all steps are necessarily carried out.

The exemplary method of FIGS. 2A to 2N is identical to that of FIGS. 1A to 1K expect for the additional steps shown in FIGS. 2B, 2F, 2K and 2M/2N.

As shown, for example, in FIG. 2B, at least one further adhesion layer 17 is provided on or deposited on a second side SD2 of the ferroelectric material or layer 3. The second side SD2 is located opposite the first side SD1. The second side SD2 is, for example, a lower side and the first side SD1 is an upper side.

As shown, for example, in FIG. 2F, at least one further diamond-like carbon layer or material 19 is provided or deposited on the further adhesion layer 17 located or deposited on the second side SD2 of the ferroelectric material or layer 3.

The further adhesion layer 17 is, for example, deposited directly on the second side SD2 of the ferroelectric material or layer 3, or directly in contact with the ferroelectric material or layer 3.

Alternatively, as shown in FIG. 2B, the further adhesion layer 17 is deposited indirectly on the second side SD2 of the ferroelectric material or layer 3, or indirectly in contact with the second side SD2 of the ferroelectric material or layer 3. There are one or more underlayers located between the further adhesion layer 17 and the ferroelectric material or layer 3.

The further adhesion layer 17 is, for example, identical to the adhesion layer 7 and deposited in an identical manner.

The further adhesion layer 17 may have a thickness greater than the thickness of the adhesion layer 7, for example between 4 and 10 times greater in thickness. The further adhesion layer 17 may have a thickness, for example, between 120 nm and 200 nm, for example, 150 nm.

The adhesion layer 7 and the further adhesion layer 17 may comprise or consist of the same material. The adhesion layer and/or the further adhesion layer comprise or consist of, for example, Silicon Nitride (Si₃N₄), Silicon Oxide (SiO₂) or Sapphire (Al₂O₃).

The adhesion layer 7 and the further adhesion layer 17 may be deposited in any order and not necessarily in the order shown in FIGS. 2B and 2C where the further adhesion layer 17 is deposited before the adhesion layer 7.

The further adhesion layer 17 is configured to assure adhesion of the diamond-like carbon layer or material (DLC) 19 to the ferroelectric material or layer 3 or to the layer(s) underlying the ferroelectric material or layer 3, in particular during processing of the device or structure.

The further adhesion layer 17 is configured to prevent delamination of the diamond-like carbon layer or material 19.

The adhesion layer 7 and/or the further adhesion layer 17, and the capping layer 11 may comprise or consist of the same material.

As mentioned, the further diamond-like carbon layer or material 19 is provided or deposited on the further adhesion layer 17, for example, directly on the further adhesion layer 17. The further diamond-like carbon layer or material 19 is identical to the diamond-like carbon layer or material 9 described previously in relation to the previous embodiment of FIGS. 1A to 1K, and can be deposited in an identical manner.

The further diamond-like carbon layer or material 19 may, for example, have a thickness between 200 nm and 1000 nm. The further diamond-like carbon layer or material 19 may have the same thickness or a thickness smaller or greater than the thickness of the diamond-like carbon layer or material 9 deposited on the first side SD1. The further diamond-like carbon layer or material 19 may have a thickness, for example, of 300 nm. The thickness is chosen so as to optimize bowing compensation.

The further diamond-like carbon layer or material 19 permits to compensate any bowing that may be present or induced due to the diamond-like carbon layer or material 9 on the first side S1 of the ferroelectric layer or material 3. The further diamond-like carbon layer or material 19 reduces, minimizes or eliminates bowing.

This assures compatibility with the processing stages of microfabrication equipment, including DUV stepper photolithography tools. A stable film was successfully obtained on the backside of the wafer, even in the case of single side polished wafers where the roughness of the backside is very high. The further adhesion layer 17 provides stability for the further diamond-like carbon layer or material 19 to adhere, even in the case of single-side polished wafers.

As shown for example in FIG. 2K, the further diamond-like carbon layer or material 19 (see, for example, FIG. 2J) is removed by etching the diamond-like carbon layer or material 19 deposited on the second side SD2 of the ferroelectric material or layer 3 to remove or fully remove the diamond-like carbon layer or material 19.

Etching is carried out in an identical manner to that of the etching the diamond-like carbon layer or material 9 deposited on the first side SD1 of the ferroelectric material or layer 3, as described previously in relation to the embodiment of FIGS. 1A to 1K.

It is noted that the etching of the diamond-like carbon layer or material 9 deposited on the first side SD1 of the ferroelectric material or layer 3 may be carried out after the etching of the diamond-like carbon layer or material 19 deposited on the second side SD2 of the ferroelectric material or layer 3, as shown in the Figures, however, etching may also be carried out in a reverse order.

As shown for example in FIGS. 2M and 2N, the further diamond-like carbon layer or material 19 (see, for example, FIG. 2J) the further adhesion layer 17 is removed in the same manner as the adhesion layer 7. The removal may be carried out simultaneously.

The other steps of this further embodiment (shown in FIGS. 2A to 2N) are identical to those described in relation to the embodiment of FIGS. 1A to 1K. As mentioned, the order of some steps may be changed and some steps may not necessarily be carried out.

The removal of the adhesion layer 7 and/or the further adhesion layer 17 provides at least partially a free-standing ferroelectric device or structure.

The present disclosure also concerns ferroelectric devices or structures FD, for example, shown in FIGS. 3A to 3D. These devices or structures FD are advantageously photolithography-ready or stepper photolithography-ready.

As shown in FIG. 3A, the ferroelectric device or structure FD comprises the ferroelectric material or layer 3, the adhesion layer 7 on (for example, directly on) the first side SD1 of the ferroelectric material or layer 3, and the diamond-like carbon layer or material 9 on (for example, directly on) the adhesion layer 7.

The ferroelectric device or structure may further include the further adhesion layer 17 (Figure, 3D) on the second side SD2 of the ferroelectric material or layer 3, and the further diamond-like carbon layer or material 19 on the further adhesion layer 17 on the second side SD2 of the ferroelectric material or layer 3.

The adhesion layer 7 is, for example, directly in contact with the ferroelectric material or layer 3. The diamond-like carbon layer or material 9 is, for example, directly in contact with the adhesion layer 7.

The further adhesion layer 17 can be, for example, indirectly in contact with the ferroelectric material or layer 3 (FIG. 3D) via underlayer(s), or alternatively, directly in contact with the ferroelectric material or layer 3 (FIG. 3C).

The further diamond-like carbon layer or material 19 is, for example, directly in contact with the further adhesion layer 17.

The ferroelectric device or structure may further include the capping or mask layer 11 (not shown) provided on the (upper) diamond-like carbon layer or material 9 provided on the adhesion layer 7 on the first side SD1 of the ferroelectric layer or material 3.

As previously mentioned, the ferroelectric material or layer 3 may comprise or consist solely of Lithium Niobate (LiNbO₃), or single crystal Lithium Niobate (LiNbO₃), or doped Lithium

Niobate (LiNbO₃) or doped single crystal Lithium Niobate (LiNbO₃). The ferroelectric material or layer 3 may comprise or consist solely of Lithium Tantalate (LiTaO₃).

The ferroelectric material or layer 3 may comprise or consist of Lithium Niobate included in or as part of a Lithium Niobate on insulator (LNOI) wafer 5 (FIGS. 3B, 3D). The Lithium Niobate on insulator (LNOI) wafer 5 may comprise or consist of the substrate 5A, the oxide layer 5B provided on the substrate 5A and the Lithium Niobate (LiNbO₃) layer 3 provided on the oxide layer 5B. The Lithium Niobate on insulator (LNOI) wafer 5 may further include the further oxide layer 5C provided on the substrate 5A opposite to the first oxide layer 5B. The substrate may, for example, comprise or consist of Silicon. The oxide layers 5B, 5C may comprise or consist of, for example, Silicon oxide.

The adhesion layer 7 and the further adhesion layer 17 may, for example, comprise or consist of the same material. The one adhesion layer and the capping or mask layer may, for example, comprise or consist of the same material.

The adhesion layer 7 and/or the further adhesion layer 17 may for example comprise or consist of Silicon Nitride (Si₃N₄), Silicon Oxide (SiO₂) or Sapphire (Al₂O₃). The capping or mask layer may for example comprise or consist of Silicon Nitride (Si₃N₄).

While the invention has been disclosed with reference to certain preferred embodiments, numerous modifications, alterations, and changes to the described embodiments, and equivalents thereof, are possible without departing from the sphere and scope of the invention. Accordingly, it is intended that the invention not be limited to the described embodiments and be given the broadest reasonable interpretation in accordance with the language of the appended claims. The features of any one of the above-described embodiments may be included in any other embodiment described herein.

1-64. (canceled)

65. A method for producing at least one ferroelectric device comprising:
providing at least one ferroelectric material inclusive layer to be structured;
depositing at least one adhesion layer on a first side of the at least one ferroelectric material inclusive layer; and
depositing at least one diamond-like carbon inclusive layer on the at least one adhesion layer.

66. The method according to claim 65, comprising:
depositing at least one further adhesion layer on a second side of the at least one ferroelectric material inclusive layer; and
depositing at least one diamond-like carbon inclusive layer on the at least one further adhesion layer deposited on the second side of the at least one ferroelectric material inclusive layer.

67. The method according to claim 66, wherein the second side is located opposite the first side.

68. The method according to claim 65, comprising the step of depositing a capping layer on the at least one diamond-like carbon inclusive layer deposited on the first side of the at least one ferroelectric material inclusive layer.

69. The method according to claim 68, wherein a thickness of the capping layer is less than a thickness of the at least one diamond-like carbon inclusive layer.

70. The method according to claim 68, further comprising the step of carrying out a photolithography process to provide at least one structured photoresist layer on the capping layer, the at least one structured photoresist layer exposing at least one portion of the capping layer.

71. The method according to claim 70, comprising etching the exposed at least one portion of the capping layer to remove the exposed capping layer to expose at least one portion of the at least one diamond-like carbon inclusive layer.

72. The method according to claim 71, further comprising etching the exposed at least one portion of the at least one diamond-like carbon inclusive layer to expose at least one portion of the at least one adhesion layer.

73. The method according to claim 72, further comprising etching the exposed at least one portion of the at least one adhesion layer to expose at least one portion of the at least one ferroelectric material inclusive layer.

74. The method according to claim 73, further comprising etching the exposed at least one portion of the at least one ferroelectric material inclusive layer.

75. The method according to claim 74, wherein the etching is carried out to at least partially produce at least one of: at least one ferroelectric device, at least one photonic device, and at least one integrated photonic device.

76. The method according to claim 66, comprising etching the at least one diamond-like carbon inclusive layer deposited on the second side of the at least one ferroelectric material inclusive layer to remove the at least one diamond-like carbon inclusive layer.

77. The method according to claim 65, comprising etching the at least one diamond-like carbon inclusive layer to remove the at least one diamond-like carbon inclusive layer from the first side of the at least one ferroelectric material inclusive layer.

78. The method according to claim 77, further comprising removing at least one of: the at least one adhesion layer and the at least one further adhesion layer.

79. The method according to claim 78, wherein removing the at least one adhesion layer (7) provides at least a partially free-standing ferroelectric device.

80. The method according to claim 65, including providing at least one or a plurality of electrodes on the at least one ferroelectric material inclusive layer.

81. The method according to claim 65, wherein the method is a wafer bonding-less method.

82. A method for producing at least one ferroelectric device comprising:
providing at least one ferroelectric material inclusive layer to be structured;
depositing at least one adhesion layer on a first side of the at least one ferroelectric material inclusive layer; and
depositing at least one silicon carbon inclusive layer on the at least one adhesion layer.

83. A ferroelectric device comprising:
at least one ferroelectric material inclusive layer,
at least one adhesion layer on a first side of the at least one ferroelectric material inclusive layer; and
at least one diamond-like carbon inclusive layer on the at least one adhesion layer.

84. Ferroelectric device according to claim 83, further comprising at least one further adhesion layer on a second side of the at least one ferroelectric material inclusive layer, and at least one diamond-like carbon inclusive layer on the at least one further adhesion layer on the second side of the at least one ferroelectric material inclusive layer.
